(19) United States
(12) Patent Application Publication
(10) Pub. No.: US 2022/0137243 A1
(43) Pub. Date: May 5, 2022

(54) RADIATION DETECTOR WITH SCINTILLATOR

(71) Applicant: SHENZHEN XPECTVISION TECHNOLOGY CO., LTD., Shenzhen (CN)

(72) Inventors: Peiyan CAO, Shenzhen (CN); Yurun LIU, Shenzhen (CN)

(21) Appl. No.: 17/571,754

(22) Filed: Jan. 10, 2022

Related U.S. Application Data
(63) Continuation of application No. PCT/CN2019/097937, filed on Jul. 26, 2019.

(51) Int. Cl. G01T 1/20

(52) U.S. Cl. CPC G01T 1/2018

(57) ABSTRACT

Disclosed herein is a radiation detector comprising: an absorption layer configured to generate a first electrical signal upon absorbing a pulse of visible light and to generate a second electrical signal upon absorbing a particle of radiation; an electronic system configured to receive a combination of the first electrical signal and the second electrical signal and configured to extract the first electrical signal from the combination of the first electrical signal and the second electrical signal.

### BACKGROUND

Radiation detectors may be devices used to measure the flux, spatial distribution, spectrum or other properties of radiations.

Radiation detectors may be used for many applications. One important application is imaging. Radiation imaging is a radiography technique and can be used to reveal the internal structure of a non-uniformly composed and opaque object such as the human body.

Early radiation detectors for imaging include photographic plates and photographic films. A photographic plate may be a glass plate with a coating of light-sensitive emulsion. Although photographic plates were replaced by photographic films, they may still be used in special situations due to the superior quality they offer and their extreme stability. A photographic film may be a plastic film (e.g., a strip or sheet) with a coating of light-sensitive emulsion.

In the 1980s, photostimulable phosphor plates (PSP plates) became available. A PSP plate may contain a phosphor material with color centers in its lattice. When the PSP plate is exposed to radiation, electrons excited by radiation are trapped in the color centers until they are stimulated by a laser beam scanning over the plate surface. As the plate is scanned by laser, trapped excited electrons give off light, which is collected by a photomultiplier tube. The collected light is converted into a digital image. In contrast to photographic plates and photographic films, PSP plates can be reused.

Another kind of radiation detectors are radiation image intensifiers. Components of a radiation image intensifier are usually sealed in a vacuum. In contrast to photographic plates, photographic films, and PSP plates, Radiation image intensifiers may produce real-time images, i.e., do not require post-exposure processing to produce images. Radiation first hits an input phosphor (e.g., cesium iodide) and is converted to visible light. The visible light then hits a photocathode (e.g., a thin metal layer containing cesium and antimony compounds) and causes emission of electrons. The number of emitted electrons is proportional to the intensity of the incident radiation. The emitted electrons are projected, through electron optics, onto an output phosphor and cause the output phosphor to produce a visible-light image.

Scintillators operate somewhat similarly to radiation image intensifiers in that scintillators (e.g., sodium iodide) absorb radiation and emit visible light, which can then be detected by a suitable image sensor for visible light. In scintillators, the visible light spreads and scatters in all directions and thus reduces spatial resolution. Reducing the scintillator thickness helps to improve the spatial resolution but also reduces absorption of radiation. A scintillator thus has to strike a compromise between absorption efficiency and resolution.

### SUMMARY

Disclosed herein is a radiation detector comprising: an absorption layer configured to generate a first electrical signal upon absorbing a pulse of visible light and to generate a second electrical signal upon absorbing a particle of radiation; an electronic system configured to receive a combination of the first electrical signal and the second electrical signal and configured to extract the first electrical signal from the combination of the first electrical signal and the second electrical signal.

According to an embodiment, the radiation is not visible light.

According to an embodiment, the radiation is X-ray or gamma ray.

According to an embodiment, the radiation detector further comprises a scintillator configured to emit the pulse of visible light upon exposure to the radiation.

According to an embodiment, the scintillator is configured to emit the pulse of visible light upon absorbing a single particle of the radiation.

According to an embodiment, the electronic system is configured to detect the single particle of the radiation based on the first electrical signal.

According to an embodiment, the first electrical signal is a first pulse of electric current and the second electrical signal is a second pulse of electric current.

According to an embodiment, the second pulse is shorter in time than the first pulse.

According to an embodiment, the absorption layer comprises an electric contact configured to collect the combination of the first electrical signal and the second electrical signal.

According to an embodiment, the electronic system comprises a filter electrically connected to the electric contact and configured to attenuate the second electrical signal from the combination of the first electrical signal and the second electrical signal.

According to an embodiment, the filter has a low-pass filter circuit, a median filter circuit, a FIR filter circuit, or a combination thereof.

According to an embodiment, the electronic system is configured to extract the first electrical signal based on a waveform of the combination of the first electrical signal and the second electrical signal.

According to an embodiment, the absorption layer comprises silicon, germanium, or a combination thereof.

According to an embodiment, the electronic system comprises an analog-to-digital converter (ADC) configured to digitize the first electrical signal.

According to an embodiment, the ADC is a successive-approximation-register (SAR) ADC.

Disclosed herein is a method comprising: receiving from an absorption layer a combination of a first electrical signal and a second electrical signal, wherein the first electrical signal is generated by the absorption layer upon absorbing a pulse of visible light and the second electrical signal is generated by the absorption layer upon absorbing a particle of radiation; extracting the first electrical signal from the combination of the first electrical signal and the second electrical signal; determining a characteristic of the radiation based on the first electrical signal.

According to an embodiment, the radiation is not visible light.

According to an embodiment, the radiation is X-ray or gamma ray.

According to an embodiment, the method further comprises emitting the pulse of visible light using a scintillator by exposing the scintillator to the radiation.

According to an embodiment, the first electrical signal is a first pulse of electric current and the second electrical signal is a second pulse of electric current.

According to an embodiment, the second pulse is shorter in time than the first pulse.

According to an embodiment, extracting the first electrical signal comprises attenuating the second electrical signal from the combination of the first electrical signal and the second electrical signal.

According to an embodiment, attenuating the second electrical signal comprises using a low-pass filter circuit, a median filter circuit, a FIR filter circuit, or a combination thereof.

According to an embodiment, extracting the first electrical signal is based on a waveform of the combination of the first electrical signal and the second electrical signal.

According to an embodiment, the absorption layer comprises silicon, germanium, or a combination thereof.

Disclosed herein is a system comprises the radiation detector described above and a radiation source, wherein the system is configured to perform radiation radiography on human mouth and teeth.

Disclosed herein is a cargo scanning or non-intrusive inspection (NII) system, comprising the radiation detector described above and a radiation source, wherein the cargo scanning or non-intrusive inspection (NII) system is configured to form an image using backscattered radiation.

Disclosed herein is a cargo scanning or non-intrusive inspection (NII) system, comprising the radiation detector described above and a radiation source, wherein the cargo scanning or non-intrusive inspection (NII) system is configured to form an image using radiation transmitted through an object inspected.

Disclosed herein is a full-body scanner system comprising the radiation detector described above and a radiation source.

Disclosed herein is a radiation computed tomography (X-ray CT) system comprising the radiation detector described above and a radiation source.

### BRIEF DESCRIPTION OF FIGURES

FIG. 1A schematically shows a cross-sectional view of a radiation detector, according to an embodiment.

FIG. 1B schematically shows a detailed cross-sectional view of the radiation detector, according to an embodiment.

FIG. 1C schematically shows an alternative detailed cross-sectional view of the radiation detector, according to an embodiment.

FIG. 2A schematically shows a component diagram of an electronic system of the detector, according to an embodiment.

FIG. 2B schematically shows the function of a filter in the electronic system of FIG. 2A.

FIG. 2C schematically shows a component diagram of an electronic system of the detector, according to an embodiment.

FIG. 2D schematically shows the function of a feature extraction circuit in the electronic system of FIG. 2C.

FIG. 3 shows a flowchart for a method, according to an embodiment.

FIG. 4-FIG. 8 each schematically show a system comprising the radiation detector described herein.

### DETAILED DESCRIPTION

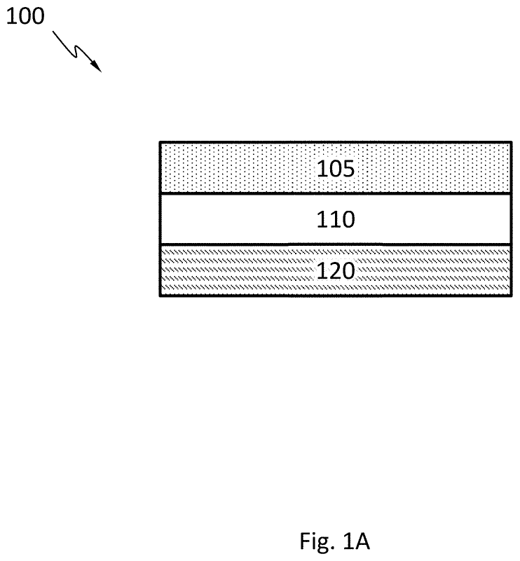

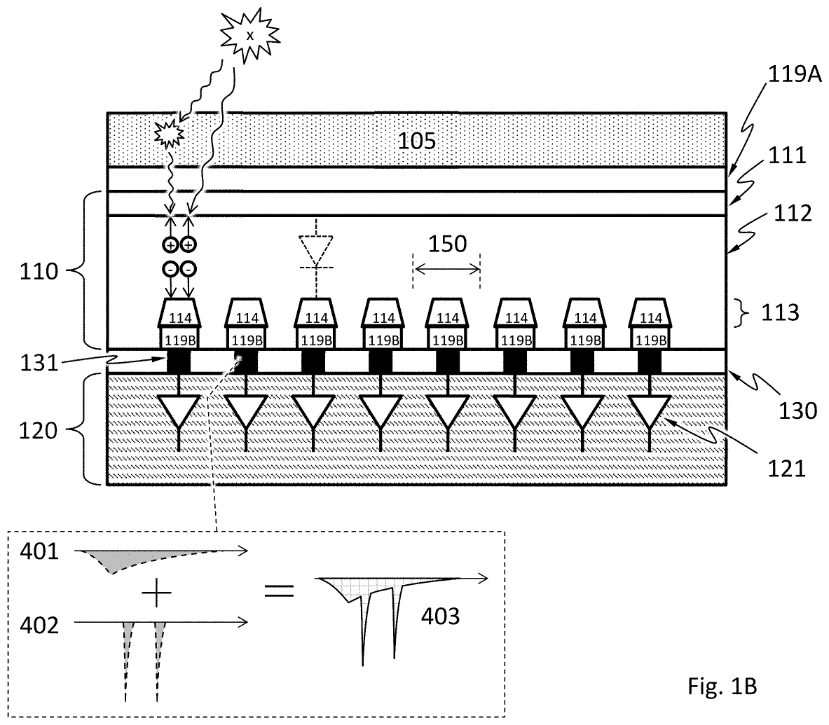

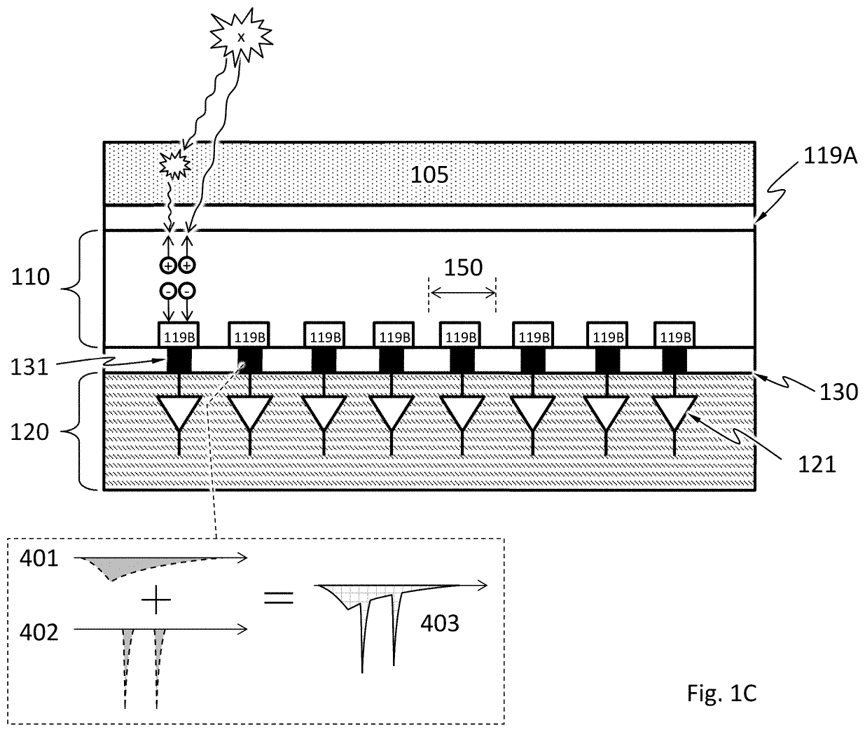

FIG. 1A schematically shows a cross-sectional view of the radiation detector 100, according to an embodiment. The radiation detector 100 may include an absorption layer 110 and an electronics layer 120. The absorption layer 110 may be configured to generate a first electrical signal 401 upon absorbing a pulse of visible light and to generate a second electrical signal 402 upon absorbing a particle of radiation. See FIG. 1B and FIG. 1C. The absorption layer 110 may include a semiconductor material such as silicon, germanium, or a combination thereof. The semiconductor material may have a high mass attenuation coefficient for visible light. The electronics layer 120 (e.g., an ASIC) may be configured to receive and analyze a combination of the first electrical signal and the second electrical signal. The radiation detector 100 may further comprise a scintillator 105, as shown in the example of FIG. 1A, which is configured to emit the pulse of visible light upon exposure to the radiation. In an embodiment, the radiation is not visible light. For example, the radiation may be X-ray or gamma ray.

As shown in a detailed cross-sectional view of the radiation detector 100 in FIG. 1B, according to an embodiment, the scintillator 105 emits a pulse of visible light when the scintillator 105 absorbs a single particle of radiation incident thereon. The particle of radiation may be an X-ray photon or a gamma ray photon. The visible light emitted from the scintillator 105 is directed to the absorption layer 110. The absorption layer 110 may include one or more diodes (e.g., p-i-n or p-n) formed by a first doped region 111, one or more discrete regions 114 of a second doped region 113. The second doped region 113 may be separated from the first doped region 111 by an optional intrinsic region 112. The discrete regions 114 are separated from one another by the first doped region 111 or the optional intrinsic region 112. The first doped region 111 and the second doped region 113 have opposite types of doping (e.g., region 111 is p-type and region 113 is n-type, or region 111 is n-type and region 113 is p-type). In the example in FIG. 1B, each of the discrete regions 114 of the second doped region 113 forms a diode with the first doped region 111 and the optional intrinsic region 112. Namely, in the example in FIG. 1B, the absorption layer 110 has a plurality of diodes having the first doped region 111 as a shared electrode. The first doped region 111 may also have discrete portions.

When visible light from the scintillator 105 hits the absorption layer 110 including diodes, the visible light may be absorbed and generate one or more charge carriers by a number of mechanisms. A pulse of visible light may generate 10 to 100000 charge carriers. The charge carriers generated by the pulse of visible light may drift to electric contacts (e.g., 119A and 119B) of one of the diodes under an electric field. The field may be an external electric field. These charge carriers may be detected by an electronic system 121 as the first electrical signal 401. The electrical contact 119B may include discrete portions each of which is in electrical contact with the discrete regions 114. In an embodiment, the charge carriers may drift in directions such that the charge carriers generated by a single pulse of visible light are not substantially shared by two different discrete regions 114 (“not substantially shared” here means less than 2%, less than 0.5%, less than 0.1%, or less than 0.01% of these charge carriers flow to a different one of the discrete regions 114 than the rest of the charge carriers). Charge carriers generated by a pulse of visible light incident around the footprint of one of these discrete regions 114 are not substantially shared with another of these discrete regions 114. A pixel 150 associated with a discrete region 114 may be an area around the discrete region 114 in which substantially all (more than 98%, more than 99.5%, more than 99.9%, or more than 99.99% of) charge carriers generated by a pulse of visible light incident in the area flow to the discrete region 114. Namely, less than 2%, less than 1%, less than 0.1%, or less than 0.01% of these charge carriers flow beyond the pixel 150.

According to an embodiment, particles of the radiation may pass through the scintillator 105 and be absorbed by the absorption layer 110, as shown in the example of FIG. 1B. One single particle of radiation may generate 10 to 100000 charge carriers in the absorption layer 110. The charge carriers generated by the particle of radiation may drift to the electric contacts (e.g., 119A and 119B) of one of the diodes under an electric field and may be detected by the electronics system 121 as the second electrical signal 402. In an example, the first electrical signal 401 is a first pulse of electric current and the second electrical signal 402 is a second pulse of electric current. The second pulse of electric current may be shorter in time than the first pulse of electric current. A combination 403 of the first electrical signal 401 and the second electrical signal 402 may be collected by the electric contact 119B.

As shown in an alternative detailed cross-sectional view of the radiation detector 100 in FIG. 1C, according to an embodiment, the absorption layer 110 may include a resistor of a semiconductor material such as, silicon, germanium, or a combination thereof, but does not include a diode. The semiconductor may have a high mass attenuation coefficient for the visible light emitted from the scintillator 105.

When the visible light from the scintillator 105 hits the absorption layer 110 including a resistor but not diodes, it may be absorbed and generate one or more charge carriers by a number of mechanisms. A pulse of visible light may generate 10 to 100000 charge carriers. The charge carriers generated by the pulse of visible light may drift to the electric contacts (e.g., 119A and 119B) of the resistor under an electric field. The field may be an external electric field. These charge carriers may be detected by the electronic system 121 as the first electrical signal 401. The electrical contact 119B includes discrete portions. In an embodiment, the charge carriers may drift in directions such that the charge carriers generated by a single pulse of visible light are not substantially shared by two different discrete portions of the electrical contact 119B (“not substantially shared” here means less than 2%, less than 0.5%, less than 0.1%, or less than 0.01% of these charge carriers flow to a different one of the discrete portions than the rest of the charge carriers). Charge carriers generated by a pulse of visible light incident around the footprint of one of these discrete portions of the electrical contact 1198 are not substantially shared with another of these discrete portions of the electrical contact 119B. The pixel 150 associated with a discrete portion of the electrical contact 1198 may be an area around the discrete portion in which substantially all (more than 98%, more than 99.5%, more than 99.9% or more than 99.99% of) charge carriers generated by a pulse of visible light incident therein flow to the discrete portion of the electrical contact 1198. Namely, less than 2%, less than 0.5%, less than 0.1%, or less than 0.01% of these charge carriers flow beyond the pixel associated with the one discrete portion of the electrical contact 119B.

According to an embodiment, particles of the radiation may pass through the scintillator 105 and be absorbed by the absorption layer 110, as shown in the example of FIG. 1C. One single particle of radiation may generate 10 to 100000 charge carriers in the absorption layer 110. The charge carriers generated by the particle of radiation may drift to the electric contacts (e.g., 119B) of the resistor under an electric field and may be detected by the electronics system 121 as the second electrical signal 402. In an example, the first electrical signal 401 is a first pulse of electric current and the second electrical signal 402 is a second pulse of electric current. The second pulse of electric current may be shorter in time than the first pulse of electric current. A combination 403 of the first electrical signal 401 and the second electrical signal 402 may be collected by the electric contact 119B.

The electronics layer 120 may include the electronic system 121 that receives a combination 403 of the first electrical signal 401 and the second electrical signal 402, for example, from the electric contact 119B. The electronic system 121 is configured to extract the first electrical signal 401 from the combination 403. The electronic system 121 may be configured to determine a characteristic of the radiation based on the first electrical signal 401. For example, the electronic system 121 may count the number of particles of the radiation absorbed by the scintillator 105 by counting a number of the first electric current pulses. For example, the electronic system 121 may determine the intensity of the radiation by integrating the first electrical signal 401 with respect to time. For example, the electronic system 121 may determine the wavelength or frequency or energy of a particle of the radiation based on the form (e.g., height, width, rate of change, etc.) of the first electrical signal 401.

The electronic system 121 may include other circuitry such as an amplifier, an integrator, a comparator, an analog-to-digital converter (ADC), a microprocessor, or a memory. The electronic system 121 may include components shared by the pixels 150 or components dedicated to a single pixel 150. For example, the electronic system 121 may include an amplifier dedicated to each pixel 150 and a microprocessor shared among all the pixels 150. The electronic system 121 may be electrically connected to the electric contact 119B by vias 131. Space among the vias may be filled with a filler material 130, which may increase the mechanical stability of the connection of the electronics layer 120 to the absorption layer 110. Other bonding techniques are possible to connect the electronic system 121 to the pixels without using vias.

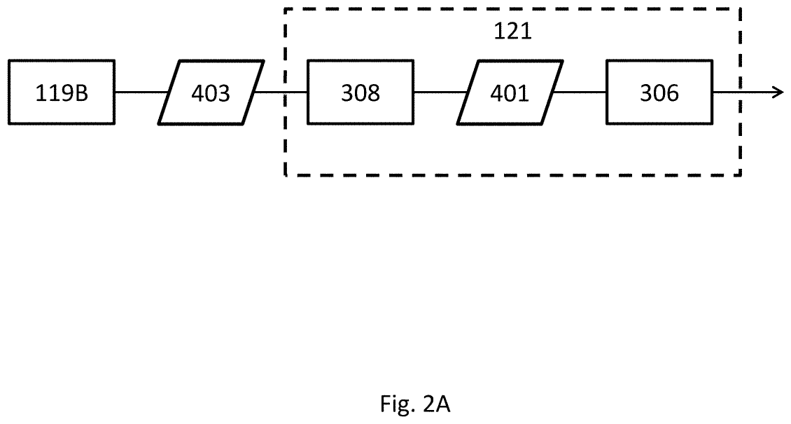

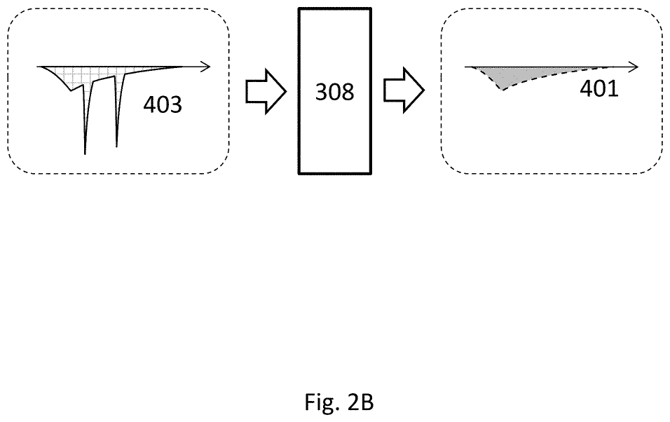

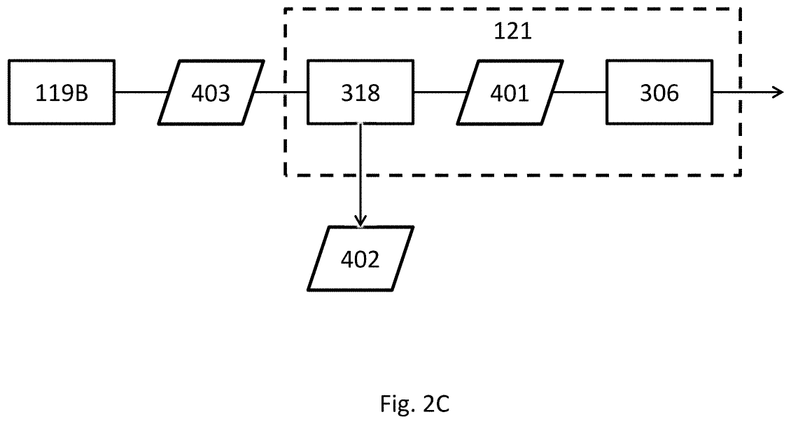

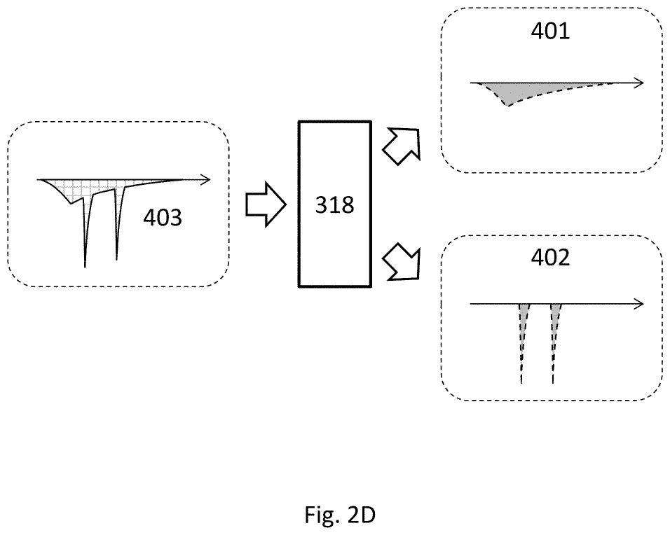

FIG. 2A schematically shows a component diagram of the electronic system 121, according to an embodiment. In this embodiment, the electronic system 121 has a filter 308. The filter 308 is electrically connected to the electric contact 119B. The filter 308 attenuate the second electrical signal 402 from the combination 403. FIG. 2B schematically shows that the combination 403 is input into the filter 308 and the first electrical signal 401 is output from the filter 308. In an example, the filter 308 has a low-pass filter circuit, a median filter circuit, a finite impulse response (FIR) filter circuit, or a combination thereof.

In an embodiment schematically shown in FIG. 2C, the electronic system 121 extracts the first electrical signal 401 from the combination 403 based on the waveform of the combination 403. For example, the FIG. 2D schematically shows that the combination 403 is input into a feature extraction circuit 318, and the first electrical signal 401 and the second electrical signal 402 are output from the feature extraction circuit 318 into separate channels. Extraction may be achieved using digital filtering, wavelet decomposition, regressive modeling, or other suitable processes.

The electronic system 121 may include an analog-to-digital converter (ADC) 306 that receives and digitizes the first electrical signal 401 from the filter 308 or from the feature extraction circuit 318. The ADC 306 may be a successive-approximation-register (SAR) ADC (also called successive approximation ADC). An SAR ADC digitizes an analog signal via a binary search through all possible quantization levels before finally converging upon a digital output for the analog signal. An SAR ADC may have four main subcircuits: a sample and hold circuit to acquire the input voltage (Vᵢₙ), an internal digital-analog converter (DAC) configured to supply an analog voltage comparator with an analog voltage equal to the digital code output of the successive approximation register (SAR), the analog voltage comparator that compares Vᵢₙ to the output of the internal DAC and outputs the result of the comparison to the SAR, the SAR configured to supply an approximate digital code of Vᵢₙ to the internal DAC. The SAR may be initialized so that the most significant bit (MSB) is equal to a digital 1. This code is fed into the internal DAC, which then supplies the analog equivalent of this digital code (V_{ref/2}) into the comparator for comparison with Vᵢₙ. If this analog voltage exceeds Vᵢₙ the comparator causes the SAR to reset this bit; otherwise, the bit is left a 1. Then the next bit of the SAR is set to 1 and the same test is done, continuing this binary search until every bit in the SAR has been tested. The resulting code is the digital approximation of Vᵢₙ and is finally output by the SAR at the end of the digitization.

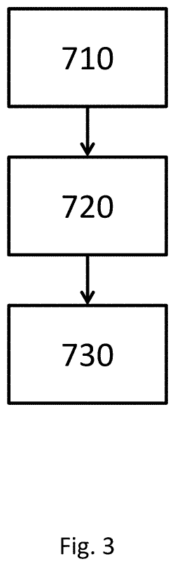

FIG. 3 shows a flowchart for a method, according to an embodiment. In procedure 710, a combination of the first electrical signal 401 and the second electrical signal 402 is received from the absorption layer 110, wherein the first electrical signal 401 is generated by the absorption layer 110 upon absorbing a pulse of visible light and the second electrical signal 402 is generated by the absorption layer upon absorbing a particle of radiation. In procedure 720, the first electrical signal 401 is extracted from the combination 403 of the first electrical signal 401 and the second electrical signal 402. According to one embodiment, extracting the first electrical signal 401 may comprise attenuating the second electrical signal 402 from the combination 403 of the first electrical signal 401 and the second electrical signal 402. Attenuating the second electrical signal 402 may comprise using a low-pass filter circuit, a median filter circuit, a FIR filter circuit, or a combination thereof. According to one embodiment, extracting the first electrical signal 401 may be based on a waveform of the combination 403 of the first electrical signal 401 and the second electrical signal 402. In procedure 730, a characteristic of the radiation based on the first electrical signal 401 is determined. One example of the characteristic is the intensity of the radiation. Another example is the frequency or wavelength of the radiation.

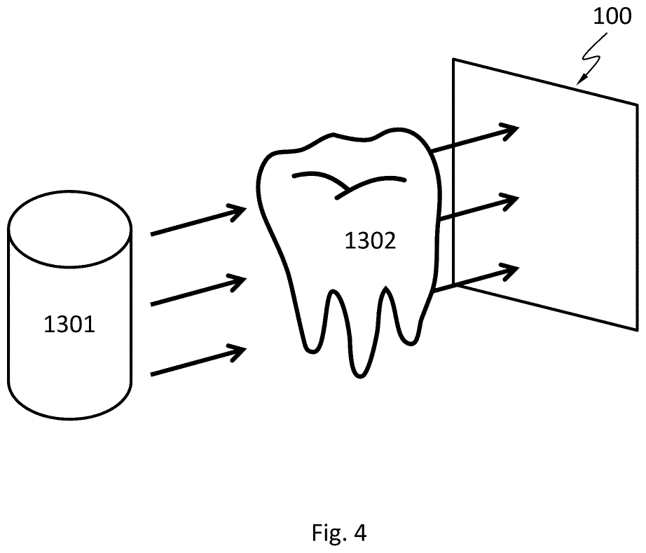

FIG. 4 schematically shows a system comprising the radiation detector 100 described herein. The system may be used for medical imaging such as dental X-ray radiography. The system comprises a pulsed radiation source 1301 that emits radiation. Radiation emitted from the pulsed radiation source 1301 penetrates an object 1302 that is part of a mammal (e.g., human) mouth. The object 1302 may include a maxilla bone, a palate bone, a tooth, the mandible, or the tongue. The radiation is attenuated by different degrees by the different structures of the object 1302 and is projected to the radiation detector 100. The radiation detector 100 forms an image by detecting the intensity distribution of the radiation. Teeth absorb radiation more than dental caries, infections, periodontal ligament. The dosage of radiation received by a dental patient is typically small (around 0.150 mSv for a full mouth series).

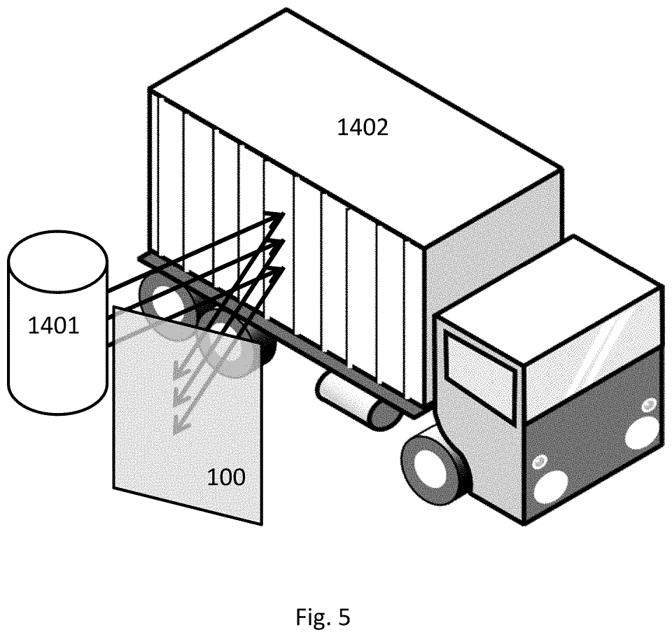

FIG. 5 schematically shows a cargo scanning or non-intrusive inspection (NII) system comprising the radiation detector 100 described herein. The system may be used for inspecting and identifying goods in transportation systems such as shipping containers, vehicles, ships, luggage, etc. The system comprises a pulsed radiation source 1401. Radiation emitted from the pulsed radiation source 1401 may backscatter from an object 1402 (e.g., shipping containers, vehicles, ships, etc.) and be projected to the radiation detector 100. Different internal structures of the object 1402 may backscatter the radiation differently. The radiation detector 100 forms an image by detecting the intensity distribution of the backscattered radiation and/or energies of the backscattered radiation.

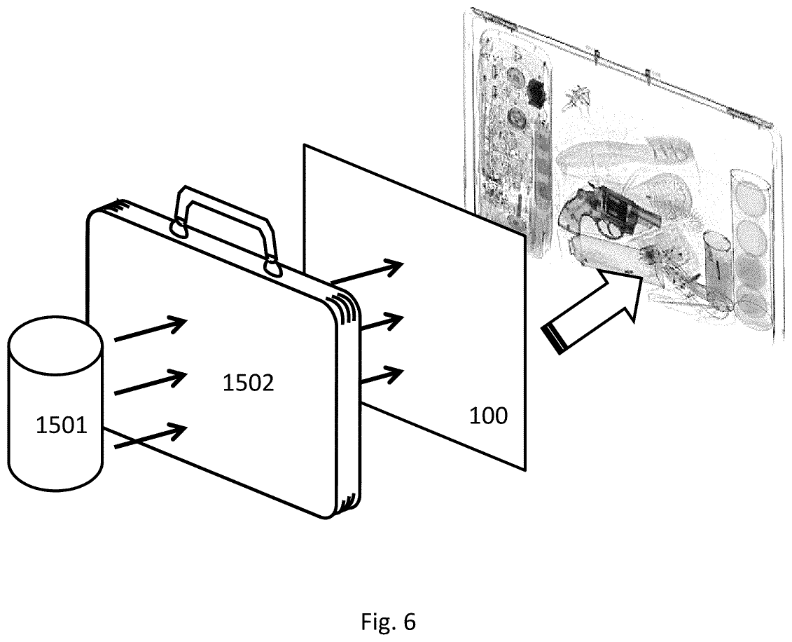

FIG. 6 schematically shows another cargo scanning or non-intrusive inspection (NII) system comprising the radiation detector 100 described herein. The system may be used for luggage screening at public transportation stations and airports. The system comprises a pulsed radiation source 1501 that emits radiation. Radiation emitted from the pulsed radiation source 1501 may penetrate a piece of luggage 1502, be differently attenuated by the contents of the luggage, and projected to the radiation detector 100. The radiation detector 100 forms an image by detecting the intensity distribution of the transmitted radiation through an object inspected. The system may reveal contents of luggage and identify items forbidden on public transportation, such as firearms, narcotics, edged weapons, flammables.

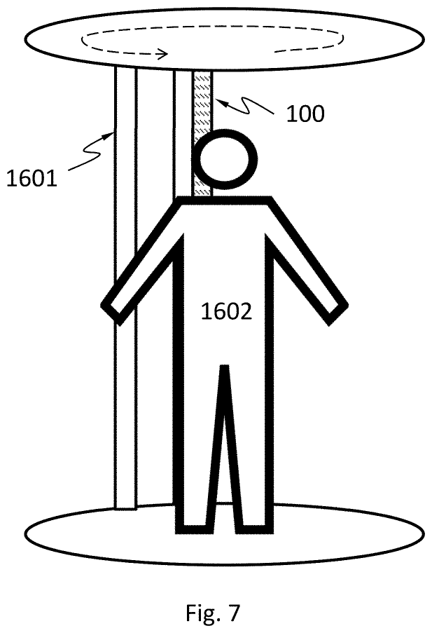

FIG. 7 schematically shows a full-body scanner system comprising the radiation detector 100 described herein. The full-body scanner system may detect objects on a person's body for security screening purposes, without physically removing clothes or making physical contact. The full-body scanner system may be able to detect non-metal objects. The full-body scanner system comprises a pulsed radiation source 1601. The radiation emitted from the pulsed radiation source 1601 may backscatter from a human 1602 being screened and objects thereon, and be projected to the radiation detector 100. The objects and the human body may backscatter the radiation differently. The radiation detector 100 forms an image by detecting the intensity distribution of the backscattered radiation. The radiation detector 100 and the pulsed radiation source 1601 may be configured to scan the human in a linear or rotational direction.

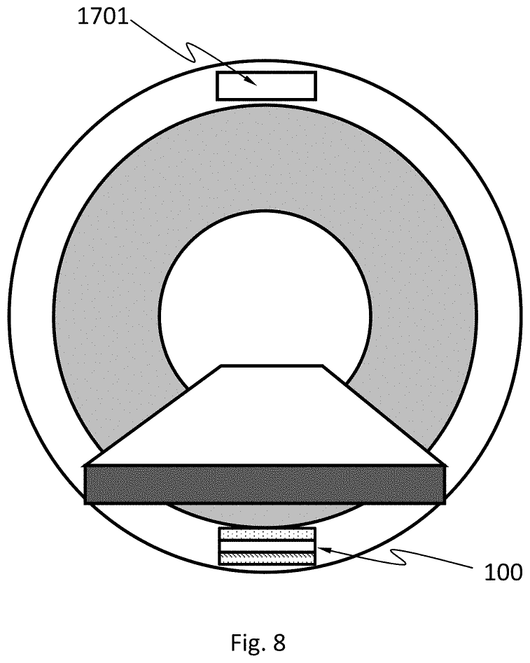

FIG. 8 schematically shows a radiation computed tomography (Radiation CT) system. The radiation CT system uses computer-processed radiations to produce tomographic images (virtual “slices”) of specific areas of a scanned object. The tomographic images may be used for diagnostic and therapeutic purposes in various medical disciplines, or for flaw detection, failure analysis, metrology, assembly analysis and reverse engineering. The radiation CT system comprises the radiation detector 100 described herein and a pulsed radiation source 1701 that emits radiation. The radiation detector 100 and the pulsed radiation source 1701 may be configured to rotate synchronously along one or more circular or spiral paths.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A radiation detector comprising:
an absorption layer configured to generate a first electrical signal upon absorbing a pulse of visible light and to generate a second electrical signal upon absorbing a particle of radiation;
an electronic system configured to receive a combination of the first electrical signal and the second electrical signal and configured to extract the first electrical signal from the combination of the first electrical signal and the second electrical signal.

2. The radiation detector of claim 1, wherein the radiation is not visible light.

3. The radiation detector of claim 1, wherein the radiation is X-ray or gamma ray.

4. The radiation detector of claim 1, further comprising a scintillator configured to emit the pulse of visible light upon exposure to the radiation.

5. The radiation detector of claim 4, wherein the scintillator is configured to emit the pulse of visible light upon absorbing a single particle of the radiation.

6. The radiation detector of claim 5, wherein the electronic system is configured to detect the single particle of the radiation based on the first electrical signal.

7. The radiation detector of claim 1, wherein the first electrical signal is a first pulse of electric current and the second electrical signal is a second pulse of electric current.

8. The radiation detector of claim 7, wherein the second pulse is shorter in time than the first pulse.

9. The radiation detector of claim 1, wherein the absorption layer comprises an electric contact configured to collect the combination of the first electrical signal and the second electrical signal; wherein the electronic system comprises a filter electrically connected to the electric contact and configured to attenuate the second electrical signal from the combination of the first electrical signal and the second electrical signal.

10. (canceled)

11. The radiation detector of claim 9 wherein the filter has a low-pass filter circuit, a median filter circuit, a FIR filter circuit, or a combination thereof.

12. The radiation detector of claim 1, wherein the electronic system is configured to extract the first electrical signal based on a waveform of the combination of the first electrical signal and the second electrical signal.

13. (canceled)

14. (canceled)

15. (canceled)

16. A method comprising:
receiving from an absorption layer a combination of a first electrical signal and a second electrical signal, wherein the first electrical signal is generated by the absorption layer upon absorbing a pulse of visible light and the second electrical signal is generated by the absorption layer upon absorbing a particle of radiation;
extracting the first electrical signal from the combination of the first electrical signal and the second electrical signal;
determining a characteristic of the radiation based on the first electrical signal.

17. The method of claim 16, wherein the radiation is not visible light.

18. The method of claim 16, wherein the radiation is X-ray or gamma ray.

19. The method of claim 16, further comprising emitting the pulse of visible light using a scintillator by exposing the scintillator to the radiation.

20. The method of claim 16, wherein the first electrical signal is a first pulse of electric current and the second electrical signal is a second pulse of electric current.

21. The method of claim 20, wherein the second pulse is shorter in time than the first pulse.

22. The method of claim 16, wherein extracting the first electrical signal comprises attenuating the second electrical signal from the combination of the first electrical signal and the second electrical signal.

23. The method of claim 22, wherein attenuating the second electrical signal comprises using a low-pass filter circuit, a median filter circuit, a FIR filter circuit, or a combination thereof.

24. The method of claim 16, wherein extracting the first electrical signal is based on a waveform of the combination of the first electrical signal and the second electrical signal.

25. (canceled)

26. (canceled)

27. (canceled)

28. (canceled)

29. (canceled)

30. (canceled)
